(19) United States
(12) Patent Application Publication
(10) Pub. No.: US 2010/0079170 A1
(43) Pub. Date: Apr. 1, 2010

(54) APPARATUS AND METHOD FOR THE ANALYSIS OF A PERIODIC SIGNAL

(75) Inventors: Heinz Mattes, Muenchen (DE); Jaafar Mejri, Ottobrunn (DE); Stephane Kirmser, Muenchen (DE); Frank Demmerle, Augsburg (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: INFINEON TECHNOLOGIES AG, Neubiberg (DE)

(21) Appl. No.: 12/240,463

(22) Filed: Sep. 29, 2008

(51) Int. Cl. H03K 5/125

(52) U.S. Cl. 327/1

(57) ABSTRACT

An apparatus and method for the analysis of a periodic signal. One embodiment provides signal values. Signs are assigned to the signal values. The signed signal values are summed to a first sum. At least one signal property is determined on the basis of the first sum.

### BACKGROUND

One or more embodiments relate to a method for the analysis of a signal. One or more embodiments relate to a method for a substantially multiplication-free analysis of a periodic signal. One or more embodiments further relate to an apparatus for analysis of a signal. Particularly, embodiments relate to an apparatus for a substantially multiplication-free analysis of a periodic signal.

Standard tasks in signal analysis include the analysis of periodic signals, particularly the determination of frequency parts of such periodic signals. An important task is the determination of the amplitude and phase of a carrier signal, especially in the presence of noise. Further, the power of the carrier signal, the amplitudes and phases of higher order harmonics, the total harmonic distortion and spurious-free dynamic range among others are important characteristics of a signal.

Standard methods performing these tasks usually use the Fast Fourier Transform (FFT). The FFT method generally needs on the order of N·log N multiplications for the analysis of a signal of which a data set with N values is provided. Additionally, on the order of N values of the trigonometric functions sine and cosine are needed, which are usually stored in a table.

However, these temporal and spatial resources needed for the Fast Fourier Transform cannot always be provided. At least, unacceptably long runtimes of the FFT algorithm may result. Systems, where these problems may occur, include, e.g., systems-on-chip (SoC) or Field Programmable Gate Arrays (FPGA) with limited hardware resources.

There is a need to reduce the requirements concerning hardware resources for certain tasks in signal analysis.

For these and other reasons, there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates a block diagram of one embodiment of a method for the analysis of a periodic signal.

FIG. 2 illustrates a block diagram of one embodiment of a method for the analysis of a periodic signal.

FIG. 3 illustrates a block diagram of one embodiment of a method for the analysis of a periodic signal.

FIG. 4A illustrates a block diagram of one embodiment of a method for the analysis of noise.

FIG. 5 illustrates a schematic view of one embodiment of an apparatus for the analysis of a periodic signal.

FIG. 6 illustrates a schematic view of one embodiment of an apparatus for the analysis of a periodic signal.

FIG. 7 illustrates a schematic view of one embodiment of an apparatus for the analysis of a periodic signal.

FIG. 8A illustrates a schematic view of one embodiment of an indexing system.

FIG. 8B illustrates a schematic view of one embodiment of an indexing system.

FIG. 8C illustrates a schematic view of one embodiment of an indexing system.

FIG. 9A illustrates a schematic view of one embodiment of a signal processing system.

FIG. 9B illustrates a schematic view of one embodiment of a signal processing system.

FIG. 9C illustrates a schematic view of one embodiment of a signal processing system.

FIG. 10 illustrates a schematic view of one embodiment of an apparatus for the analysis of a periodic signal.

FIG. 11 illustrates an exemplary graph of a reference signal according to one embodiment.

FIG. 12A illustrates an exemplary graph of reference signals according to one embodiment.

FIG. 12B illustrates an exemplary graph of reference signals according to one embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

According to one embodiment, a method for the analysis of a periodic signal is provided. The method includes providing signal values, assigning signs to the signal values, summing the signed signal values to a first sum, and determining at least one signal property on the basis of the first sum.

According to a further embodiment, an apparatus for the analysis of a periodic signal is provided. The apparatus includes a signal value holding system configured to provide signal values, a first signal value processing unit configured to assign signs to the signal values and configured to sum the signed signal values to a first sum. The apparatus is configured to provide, on the basis of the first sum, information about at least one property of the periodic signal.

One or more embodiments are also directed to methods for operating the disclosed apparatus. These methods may be performed manually or automated, e.g., controlled by a computer programmed by appropriate software, by any combination of the two or in any other manner.

Reference will now be made in detail to the various embodiments, one or more examples of which are illustrated in each figure. Each example is provided by way of explanation and is not meant as a limitation. For example, features illustrated or described as part of one embodiment can be used on or in conjunction with other embodiments to yield yet a further embodiment. It is intended that the present disclosure includes such modifications and variations.

Within the description of the drawings, the same reference numbers refer to the same components. Generally, only the differences with respect to the individual embodiments are described.

The term “substantially multiplication-free”, as referred to herein, includes, but is not limited to, “without multiplications” or “with a constant number of multiplications”. If an algorithm or method acts on an input set of N data items, and needs, e.g., O(N) additions to complete, the term “substantially multiplication-free” would mean a number of multiplications of order less than O(N), e.g., a constant number of multiplications or a logarithmically growing number of multiplications. More generally, the term “substantially multiplication-free” is understood with respect to any algorithmic complexity. If a method has an algorithmic complexity A with respect to additions, the method is “substantially multiplication-free” if it uses multiplications with algorithmic complexity less than A.

The term “signal” as used herein may refer to an actual physical signal. The term “signal” may also refer to values, functions, function tables or graphs representing the signal.

An important task in signal analysis is the determination of the amplitude and phase of a carrier signal, especially in the presence of noise. Further, the power of the carrier signal, the amplitudes and phases of higher order harmonics, the total harmonic distortion and spurious-free dynamic range among others are important characteristics of a signal. It is desirable that the precision with which such quantities are determined can be chosen or programmed.

A harmonic signal with amplitude A and phase φ is a signal of the form

fₕₐᵣₘ(x)=A sin(x+φ)=C cos(x)+S sin(x) (1)

where x=ωt, ω is the angular frequency and t time, and

A=\sqrt{S²+C²} (2)

and

φ=arctan(S/C) (3)

The harmonic signal may, e.g., be a carrier signal. The carrier signal may be disturbed by noise, e.g., noise of the form

$$ε ( x ) = {\sum }_{m = 2}^{M} {a}_{m} cos ( mx ) + {\sum }_{m = 2}^{M} {b}_{m} sin ( mx ) \qquad ( 4 )$$

where M is an integer larger than or equal to 2, and aₘ, bₘ are real-valued coefficients and x=ωt as above.

The resulting signal, called test signal herein, is a superposition of the form

fₜₑₓₜ(x)=A sin(x+φ)+e(x)=C cos(x)+S sin(x)+e(x) (5)

Amplitude and phase, respectively the corresponding quantities S and C, can be determined by multiplying the test signal with harmonic reference signals of angular frequency ω and known phase, e.g.,

f_{ref}(x)=sin(x) (6)

and

f_{ref}(x)=cos(x) (7)

where x=ωt and integrating over a full period, namely

$$\begin{matrix}I = \frac{1}{2 π} {\int }_{x = 0}^{2 π} {f}_{test} ( x ) sin ( x ) d x & ( 8 ) \\ Q = \frac{1}{2 π} {\int }_{x = 0}^{2 π} {f}_{text} ( x ) cos ( x ) d x & ( 9 )\end{matrix}$$

By integrating over a full period, all harmonic terms are integrated out, i.e., they do not contribute to the final value of the integral. Only constant terms, resulting by sum and difference identities in the multiplication of trigonometric functions, contribute to the integral. The integral of equation (8) evaluates to S/2, the integral of equation (9) evaluates to C/2. Integrals of the form of equation (8), also with more general reference functions than a sine function, are referred to as I integrals herein. Integrals of the form of equation (9), also with more general reference functions than a cosine function, are referred to as Q integrals herein.

Thus, at least in principle, amplitude and phase and other characteristic properties of the carrier signal can be determined, e.g., the power P=(S²+C²)/2=2(I²+Q²). The noise may also be analyzed. To determine the coefficients aₘ, bₘ, harmonic reference signals with angular frequency mω may be used instead of reference signals with angular frequency ω, where m is larger than or equal to 2.

However, while analog, non-digital integrators may perform such integrations, e.g., of real-world test signals which are multiplied electronically by real-world reference signals, in digital systems the values of a test signal are often known only at N discrete positions, where N is an integer. Integration may be replaced by a weighted sum. Typically, the values of the test signal are available in some indexed form, e.g., as a table. These values have to be multiplied by corresponding discrete values of reference signals. The values of the reference signals are usually also taken from a table. Both the table of reference values as well as the multiplication of all individual discrete test signal values with corresponding reference signal values are resource-demanding, at least for certain systems with limited storage or processing capabilities, e.g., Systems on Chip (SoCs) or Field Programmable Gate Arrays (FPGAs). Systems with limited resources may be present in processes such as production tests or built-in self-tests of SoCs, e.g., adaptive predistortion or equalizer modules used in communication hardware. Afterwards, numerical integration is performed, which costs additional resources.

According to one or more embodiments, a method for analyzing a periodic signal, typically the amplitude and phase of a periodic signal, is provided. Typically, the analysis of the signal is substantially multiplication free. In one or more embodiments, no specific values of reference functions such as sine or cosine functions are needed. Therefore, a method for analyzing a periodic signal is provided with reduced need of resources, e.g., hardware resources such as storage space or processing elements, or software resources or any other temporal or spatial resources. Therein, according to one or more embodiments, computation time depends only linearly on the number of test signal values N leading to high processing speed and good scalability. In one embodiment, assuming a measurement precision of 0.5%, an increased speed by, e.g., a factor of two, or a space savings by a factor of 10 might be possible.

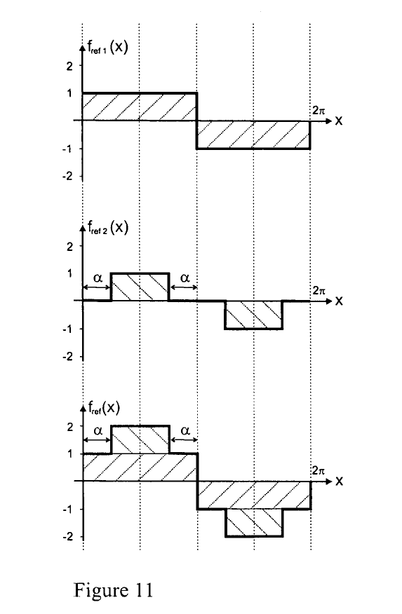

Multiplications may be substantially avoided by using rectangular functions or square wave functions as reference signals, namely functions of the form

$$\begin{matrix}{f}_{ref} ( x ) = \{ \begin{matrix}+ 1 & α \leq x < π - α \\ - 1 & π + α \leq x < 2 π - α \\ 0 & else\end{matrix} \\ or & ( 10 ) \\ {f}_{ref} ( x ) = \{ \begin{matrix}+ 1 & 0 \leq x < π / 2 - α \\ - 1 & π / 2 + α \leq x < 3 π / 2 - α \\ + 1 & 3 π / 2 + α \leq x < 2 π \\ 0 & else\end{matrix} & ( 11 )\end{matrix}$$

where x=ωt and 0≦α≦π/2. In one or more embodiments, superpositions of such functions are used, which will be explained later. By using these rectangular or square wave functions, only assignments of positive or negative signs have to be performed instead of floating point multiplications, or a filtering of signal values. These operations correspond to multiplications with reference functions which only assume the values −1, 0, and +1. Positive signs are assigned to signal values where a corresponding reference function assumes the value +1, negative signs are assigned where a corresponding reference function assumes the value −1. Where a corresponding reference function assumes the value 0, i.e., outside of the support of a corresponding reference function, a signal value is filtered or discarded. Filtering may depend on a filter criterion, e.g., determined by the parameter α, which may determine the support of the reference function. Examples of such reference functions are illustrated in FIG. 11. The top graph illustrates a rectangular reference function f_{ref 1}(x), which is a function according to equation (10) with parameter α=0. The graph in the middle illustrates a rectangular reference function f_{ref 2}(x), which is a function according to equation (10) with parameter α=π/4. The bottom graph illustrates a superposition of the reference functions f_{ref 1}(x) and f_{ref 2}(x).

Instead of shifting the reference signal, e.g., by π/2, to obtain the second reference function from the first in the previous paragraph, alternatively the carrier signal may be shifted. Shifting a sine function by π/2 results in a cosine function. If there are N carrier signal values evenly distributed in the interval zero to 2π, then a shift by N/4 when indexing the values in natural order corresponds to a π/2 shift. Indexing in natural order means indexing by a rising sequence in a totally ordered indexing set, e.g., by the numbers 0 to N−1, wherein signal values corresponding to later times t=x/ω are indexed by larger indices.

When processing the test signal with these reference functions, numerical integration may then be performed by simply adding up the values. Possibly, a final normalization or denormalization is done. Thus, substantially only additions are used.

The result of the analytical integration is

$$\begin{matrix}I = \frac{1}{π} ( {S}_{1} cos α + {\sum }_{m = 1}^{M} \frac{cos [ ( 2 m + 1 ) α ] {b}_{2 m + 1}}{2 m + 1} ) & ( 12 ) \\ Q = \frac{1}{π} ( {C}_{1} cos α + {\sum }_{m = 1}^{M} \frac{cos [ ( 2 m + 1 ) α ] {a}_{2 m + 1}}{2 m + 1} ) & ( 13 )\end{matrix}$$

which is based on a representation of the reference function of equation (10) in the form

$${f}_{ref} ( x ) = \frac{4}{π} {\sum }_{m = 0}^{∞} \frac{cos [ ( 2 m + 1 ) α ]}{2 m + 1} sin [ ( 2 m + 1 ) x ] \qquad ( 14 )$$

and on a representation of the reference function of equation (11) in the form

$${f}_{ref} ( x ) = \frac{4}{π} {\sum }_{m = 0}^{∞} \frac{cos [ ( 2 m + 1 ) α ]}{2 m + 1} cos [ ( 2 m + 1 ) x ] \qquad ( 15 )$$

and amplitude A and phase φ are estimated, possibly up to a normalization, by the terms

A=2\sqrt{I²+Q²} (16)

φ=arctan(I/Q) (17)

The terms with the coefficients aₘ, bₘ contribute to an error in the estimation of A and φ. This error can be estimated, e.g., by a worst-case, or at least bad-case, estimation of the error, e.g., with white noise. In one or more embodiments, the error is tolerable or negligible. In other embodiments, ways to reduce this error are used, which will be discussed later. Numerical integration also contributes to the error. Errors due to numerical integration are well-known and shall not be discussed herein. The parameter α can be freely chosen. According to one or more embodiments, the parameter α is set to zero, which corresponds to a rectangular reference signal function with full support on the interval zero to 2π. An example is the function illustrated in the top graph in FIG. 11. According to other embodiments, the parameter α is optimized analytically or numerically or by a combination thereof or in any other way.

In one or more embodiments, information about the carrier signal is known a priori. For example, if it is known that the phase φ of the carrier signal is zero, then the Q integral or an analog thereof need not be computed, saving time and other resources.

As illustrated in FIG. 1, according to one embodiment, a method for the analysis of a periodic signal, typically a harmonic signal or harmonic wave disturbed by noise, is provided. In further, typical embodiments, a method for a substantially multiplication-free analysis of a periodic signal is provided. The method includes providing signal values 110. In one or more embodiments, ordered or indexed or tabulated signal values are provided. In one or more embodiments, the signal values are provided as a data set, for example as a data table or in any other indexed or ordered form. In alternative embodiments, the signal values are provided on the fly, i.e., typically, one by one or in small groups and just in time for further processing. Provision on the fly may save resources such as storage space. Generally, providing signal values may also include providing an arbitrary number of copies of values representing a signal such as a test signal. Provision of signal values is related to providing a test signal.

As illustrated in FIG. 1, the method further includes assigning signs to the signal values 130. In one or more embodiments, signs are assigned to all signal values. In other embodiments, assigning signs to the signal values includes assigning signs to only part of the signal values and/or discarding part of the signal values. Generally, assigning signs may include assigning signs to the values representing a signal and/or an arbitrary number of copies of these values, wherein the same or different signs may be assigned to each copy of a specific value. Assigning signs is related to a multiplication by at least one reference signal, typically a rectangular signal function.

The method further includes summing the signed signal values 140. According to one or more embodiments, all signed signal values are summed. According to other embodiments, only part of the signed signal values is summed. Generally, summing signed signal values may include summing an arbitrary number of copies of a specific value partly representing a signal. Therein, each specific copy of such a value may have the same or a different sign as compared to each further copy. Summation may include summation to one single sum. In one embodiment, summation may include summation to several sums. For example, a set of signal values may consist of a subset of values representing a signal and a copy thereof. A first set of signs is assigned to the subset, and a second set of signs is assigned to the copy. The subset with first signs is summed to a first sum, and the copy with second signs is summed to a second sum. Summing signed signal values is related to integration of a signal which related to the product of the test signal and a reference signal, typically a rectangular reference function.

The method includes determining a signal property from information including the sum 150. As illustrated in FIG. 1, according to one or more embodiments, at least one signal property of the test signal, e.g., the amplitude and/or the phase of the carrier signal, may be determined from the outcome of summing the signal values, namely from one or more sums or on the basis of one or more sums. In other embodiments, at least one signal property may be determined from the outcome of summing the signal values and additional information, e.g., knowledge that the phase of the carrier signal is zero or its amplitude is one. Determining a signal property may include further computational processing such as normalizing sums. Normalizing may include division by the length of the period of the carrier signal or may include other operations. Determining a property may be a determining of the property up to errors, typically tolerable or negligible errors.

In one embodiment, N values representing the test signal are provided as signal values. Here, for simplicity, N is an integer which can be divided by four. The N values are provided as indexed values in a natural order. The carrier signal has a phase equal to zero. The reference function is a rectangular function with full support, i.e., α is equal to zero. Hence, a plus sign is assigned to the first N/2 values, i.e., to the values indexed, e.g., by the indices 0 to N/2-1. A negative sign is assigned to the second N12 values, i.e., to the values correspondingly indexed by the indices N/2 to N−1. All values are added to a first sum related to the integral I. The amplitude of the carrier signal is determined, up to errors due to the noise or the numerical integration, after normalization of the first sum as in equation (11) above, albeit simplified because Q=0.

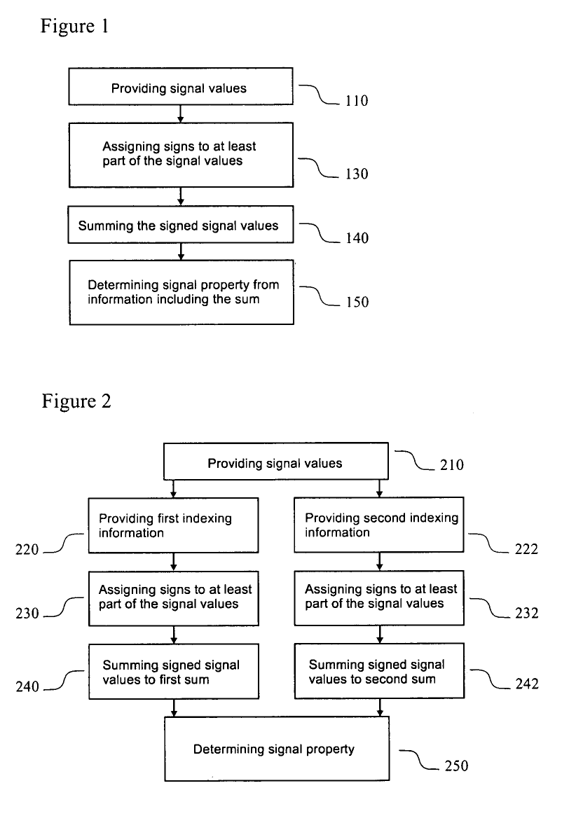

In another embodiment, the same situation is considered, but the phase of the carrier signal is unknown. Now, also copies of the N values from the previous embodiment are provided. A further reference function is now chosen similar to the function of the previous example, but shifted by π/2. Correspondingly, a plus sign is assigned to the copies of values with indices 0 to N/4-1 and 3N/4 to N−1, while a negative sign is assigned to the copies of values with indices N/4 to 3N/4-1. The copies of values with these signs are summed to a second sum corresponding to the integral Q. After normalization of the second sum, amplitude and phase of the carrier signal can be determined from the second sum and from the first sum of the previous example, again up to errors due to the noise or the numerical integration. This embodiment is illustrated in FIG. 1, and, in one embodiment detailed in FIG. 2.

Further embodiments are illustrated in FIG. 2. According to one embodiment, FIG. 2 schematically illustrates a method for the analysis of a periodic signal related to forming an I integral and a Q integral. Therein, signal values are provided 210. First indexing information is provided with respect to the signal values 220. First signs are assigned to the signal values 230. In one or more embodiments, first signs are assigned to the signal values based on the first indexing information. First signs may be assigned to all or a part of the signal values. The signal values signed with first signs are summed to a first sum 240. The first sum is related to the I integral. According to embodiments, second indexing information is provided 222. Second signs are assigned to the signal values 232. Second signs may be assigned to copies of the signal values. In one or more embodiments, second signs are assigned to the signal values based on the second indexing information. Second signs may be assigned to all or a part of the signal values. The signal values signed with second signs are summed to a second sum 242. The second sum is related to the Q integral. In one or more embodiments, at least one signal property is determined 250. In typical embodiments, at least one signal property is determined from the first and the second sum. In other embodiments, at least one signal property is determined based on the first and second sum.

According to further embodiments, the error due to noise is reduced. Therein, superpositions of rectangular reference signals are used. Typically, superpositions of rectangular reference signals each with different support are used, i.e., with different parameters α. In typical embodiments, the superposition of rectangular reference signals approximates a sine function or multiple thereof, respectively a cosine function or multiple thereof, because, in principle, a sine/cosine function or multiple thereof allows for an exact determination of amplitude and phase of a carrier signal apart from errors due to numerical integration. In one or more embodiments, the parameters α are optimized, either analytically or numerically, to make the error due to the noise as small as possible. In other embodiments, the parameters are freely chosen. Superposing reference signals, i.e., superposing the corresponding functions, is a linear operation involving addition. Therefore, with superposed rectangular reference signals, the method is still substantially multiplication-free.

In an embodiment, as illustrated in FIG. 11, a reference signal is the superposition of two rectangular functions. One of these two functions is a rectangular function with parameter α₁=0. The other is a rectangular function with parameter α₂. In this embodiment, the reference signal approximates a sine function, more particularly a sine function multiplied by two. When multiplying a test signal with this reference signal and integrating over a period of the carrier signal, the resulting I integral should be divided by two and, possibly, further normalized for extraction of signal properties such as amplitude or phase of the carrier signal. Also, the reference signal may be normalized.

In this embodiment, N values representing the test signal are provided as signal values. Here, for simplicity, N is an integer which can be divided by two. The N values are provided as indexed values in a natural order. The carrier signal has a phase equal to zero. The reference function is the reference function illustrated in the bottom graph of FIG. 11. Hence, a plus sign is assigned to the first N12 values, i.e., to the values indexed, e.g., by the indices 0 to N/2-1. A negative sign is assigned to the second N/2 values, i.e., to the values correspondingly indexed by the indices N/2 to N−1. All values are added to a first sum. Also, copies of the N values are provided. Further, a positive sign is assigned to the copies of values with indices corresponding to values of the test signal which are in the interval from α to π−α, while a negative sign is assigned to the copies of values with indices corresponding to values of the test signal which are in the interval from π+α to 2π−α. The copies of values with these signs are summed to a second sum. Adding the first and second sum yields a quantity related to the I integral times a factor, namely

$$\begin{matrix}I = {I}_{1} + {I}_{2} \\ = \frac{1}{π} ( ( 1 + cos α ) {S}_{1} + {\sum }_{m = 1}^{M} \frac{\{ 1 + cos [ ( 2 m + 1 ) α ] \} {b}_{2 m + 1}}{2 m + 1} )\end{matrix} \qquad ( 18 )$$

After normalization, the amplitude of the carrier signal can be determined as explained above, again up to errors due to the noise and/or due to the numerical integration.

According to a further embodiment, FIG. 2 schematically illustrates a method for the analysis of a periodic signal related to forming an I integral for a reference function which is a superposition of rectangular functions. Therein, signal values are provided 210. First and second indexing information is provided 220, 222. The first and second indexing information may be the same. First signs are assigned to the signal values 230. In one or more embodiments, first signs are assigned to all signal values. In other embodiments, first signs are assigned to only part of the signal values. Another part of the signal values may be filtered out or discarded. Further, in one or more embodiments, second signs are assigned to the signal values 232. The second signs may be assigned to only part of the signal values. Another part of the signal values may be filtered out or discarded. Typically the part of the signal values to which second signs are assigned is different from the part of signal values to which first signs are assigned. The signal values signed with first signs are summed to a first sum 240. The signal values signed with second signs are summed to a second sum 242. In further embodiments, at least one signal property is determined 250. Determination of at least one signal value may be based on the first and second sum, e.g., on the sum of the first and second sum. Determination of at least one signal value may include normalization, other arithmetic operations or other operations.

In embodiments, which may be combined with any embodiments described herein, the reference signal may be represented by a superposition of n rectangular functions, each with a corresponding parameter α. In one or more embodiments, these parameters may be determined by optimization, e.g., by minimization of the error due to the noise or the numerical integration. In other embodiments, the parameters α may be freely chosen. According to embodiments described herein, the rectangular functions forming the superposition reference signal may have step heights with value 1. According to other embodiments, the step heights may have values different from one. Step heights may be determined by an optimization, e.g., by minimization of the error due to the noise or the numerical integration. Step heights may be freely chosen or determined in any other way. In one embodiment, a method for signal analysis according to embodiments described herein, which uses reference functions which are superpositions of n rectangular functions may be substantially multiplication-free. Such a method may, e.g., require n normalizations of sums, i.e., a constant number of multiplications. Generally, using a superposition of n rectangular functions instead of only one may allow to better approximate a sine or cosine reference signal, thereby reducing errors due to the noise.

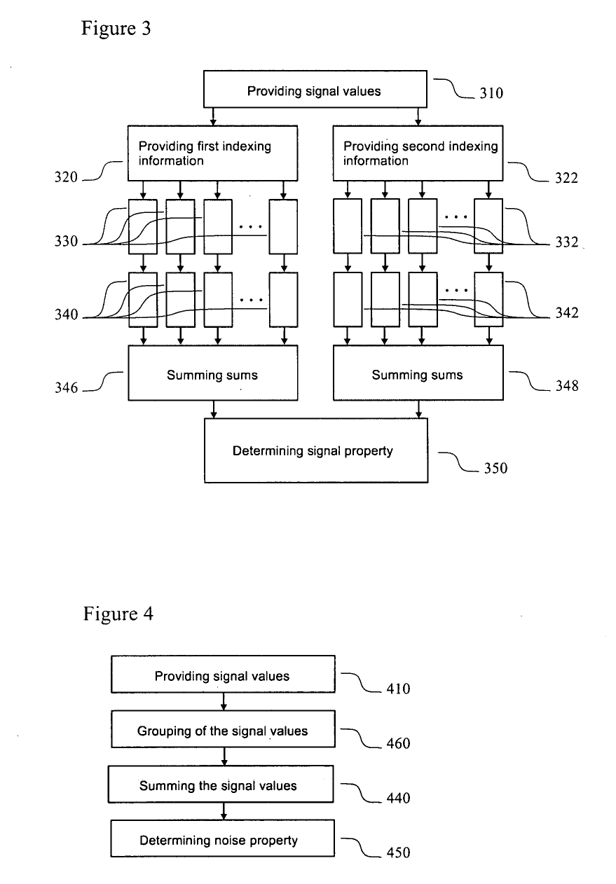

In FIG. 3, a method of analyzing a periodic signal is illustrated. Therein, signal values are provided 310. The method further includes providing first indexing information 320. According to embodiments, signs are assigned to the signal values 330. According to one or more embodiments, n sets of signs are assigned to the signal values. According to other embodiments, n sets of signs are assigned to parts of the signal values. Typically, each set of signed signal values is summed to one out of n sums 340. In one or more embodiments, some or all of the n sums may further be weighted by a factor or normalized. The sums may further be summed 346. The result of this summation may, in one or more embodiments, be weighted or normalized. This result of summation may, e.g., be related to forming an I integral.

According to embodiments, second indexing information is provided 322 as illustrated in FIG. 3. The second indexing information may, e.g., provide shifted indices to the signal values, i.e., indices which are shifted as compared to the first indexing information. According to embodiments, signs are assigned to the signal values 332. According to one or more embodiments, n sets of signs are assigned to the signal values. According to other embodiments, n sets of signs are assigned to parts of the signal values. Typically, each set of signed signal values is summed to one out of n sums 342. In one or more embodiments, some or all of the n sums may further be weighted by a factor or normalized. The sums may further be summed 348. The result of this summation may, in one or more embodiments, be weighted or normalized. This result of summation may, e.g., be related to forming a Q integral.

As further illustrated in FIG. 3, the method of signal analysis may further include determining at least one signal property 350. The at least one signal property may, e.g., be at least one property out of the group including amplitude, phase, and power, all either of the carrier signal or, as explained below, of the noise. The group of signal properties may further include total harmonic distortion and spurious-free dynamic range.

According to further embodiments, which can be combined with other embodiments described herein, a method of analyzing a periodic signal is provided. In one embodiment, a method of analyzing the noise part of a periodic signal, e.g., a periodic test signal, is provided. More specifically, a method for analyzing higher harmonics in a periodic signal with base frequency ω is provided.

To determine the noise coefficients aₘ, bₘ in a periodic test signal, e.g., a test signal as in equations (4), (5), harmonic reference signals with angular frequency mω may be used instead of reference signals with angular frequency ω, where m is larger than or equal to 2. When multiplying the test signal by such harmonic reference signals of higher angular frequency mω, and integrating over a full period, again only the constant terms will contribute to the value of the integral. However, due to sum and difference identities of trigonometric functions, the constant terms now include terms with coefficients aₘ, bₘ, typically depending on whether a sine or cosine reference signal of angular frequency mω was used as reference signal. In such a way, these coefficients may be extracted.

With rectangular reference signals, other terms including undesired coefficients may contribute to the integral or the integrals as error terms. In one or more embodiments, these errors may be tolerable or negligible. In other embodiments, the errors may be reduced using superpositions of n rectangular reference signals, where n is larger than or equal to two. As explained above, rectangular reference signals enable a substantially multiplication-free determination of signal properties. Properties of the noise signal may, according to embodiments described herein, be determined substantially without multiplications.

According to one or more embodiments, signal values are provided. A rectangular reference signal or a superposition of n rectangular reference signals is provided, which may approximate a sine or cosine function of angular frequency mω. Multiplication of the signal values by the reference signal amounts to an assigning of corresponding signs. Hence, in one or more embodiments, signs are assigned to the signal values or a part thereof. In other embodiments, n sets of signs are assigned to the signal values or parts thereof. The signed signal values are summed to a sum or to n sums. The sums may be weighted or normalized. This sum, or a sum of the n sums, corresponds to an integral over a period of the test signal, possibly after normalization. From the summation result, and, optionally, from additional information about the signal, at least one signal property can be determined, e.g., an amplitude or amplitudes of the noise may be determined. These embodiments are, e.g., illustrated in FIG. 1.

According to further embodiments, reference signals corresponding to or approximating sine or cosine functions of higher angular frequency mω, m≧2, need not be provided for extracting information about the noise. Instead, indexing information is provided. According to one or more embodiments, the indexing information corresponds to a mapping of indices of the signal values.

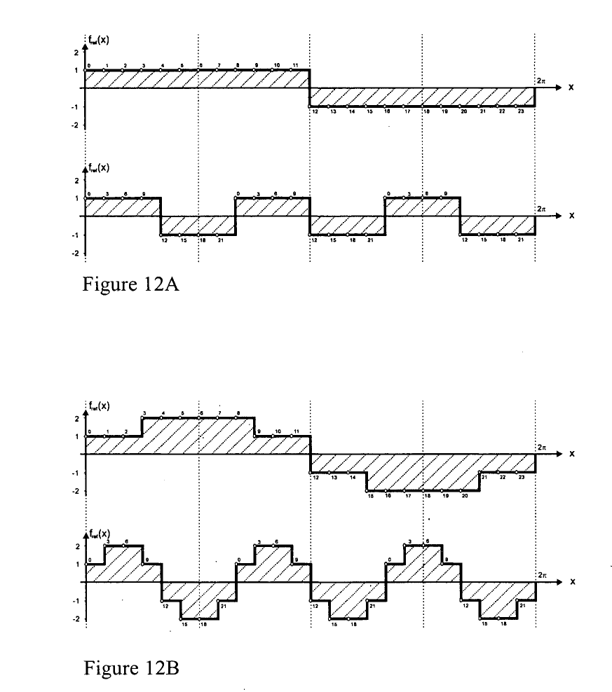

FIG. 12A illustrates such a mapping. According to embodiments described with reference to FIG. 12A, N=24 signal values are provided indexed by indices 0 to 23 in natural order. Correspondingly, multiplication by the rectangular reference signal illustrated in the top part of FIG. 12A amounts to assigning a positive sign to the signal values 0 to 11, and a negative sign to the signal values 12-23. By summing the signed signal values, a value related to an I integral may be obtained and properties of the carrier signal be extracted. As illustrated in the bottom part of FIG. 12A, providing indexing information which maps the indices assigned to the signal values corresponds to generating a reference signal of shorter period, i.e., corresponding to or approximating a higher angular frequency reference signal. In FIG. 12A, indexing information is generated by the mapping

i [symbol] (3i)mod 24 (19)

where signal value index i runs from 0 to 23. The modulo operation mod has as outcome the remainder of an integer division. In the embodiments illustrated in FIG. 12A, after providing each signal value also with the mapped value, a positive sign is assigned to signal values with mapped signal value indices 0-11 (corresponding to the signal values 0-3, 8-11, 16-19), and a negative sign is assigned to signal values with mapped signal value indices 12-23 (corresponding to the signal values 4-7, 12-15, 20-23). By summing the signed signal values, a value corresponding to an I integral may be obtained and properties of the noise be extracted. In the embodiments described above with respect to FIG. 12A, the coefficient b₃ may be determined up to errors due to noise terms and/or due to the carrier signal terms.

Generally, assigning indexing information may include generating indexing information. Indexing information may be generated by the mapping

i [symbol] (ki)mod N (20)

where index i may run from 0 to N−1, k is the desired harmonic about which information is to be extracted, and N is the number of values representing the test signal. Also, generally, indexing information may be generated by the mapping

i [symbol] [ki+N/4k] mod N (21)

typically in connection with analogs to a Q integral. The term N/4k may be rounded to the closest integer value. Generating or obtaining indexing information may be based on a consecutive numbering, e.g., equation (18) is based on an indexing by consecutive integers i. Generating or obtaining indexing information may be further based on an increment operation, e.g., a multiplication of i by k in equation (18). Further, generating or obtaining indexing information may be based on a modulo operation, e.g., a modulo N operation in equation (18). Generating or obtaining indexing information may be based on a shift operation, e.g., addition of a summand N/4k in equation (19). Alternatively, generation of indexing information may be done in any other way.

In embodiments, which may be combined with other embodiments described herein, superpositions of rectangular reference signals may used for determining properties of the noise. Thereby, errors may be reduced. As exemplarily illustrated in FIG. 12B, a superposition of two rectangular functions is used, one with full support, i.e., α=0, and one with parameter α=π/4. The same mapping of the indices as explained with respect to FIG. 12A provides indexing information. According to one or more embodiments, signal values outside the support of a respective rectangular function are not assigned a sign. Signed signal values are summed. The sum may be normalized, e.g., by a factor including a factor of two in the exemplary embodiment illustrated in FIG. 12B. According to other embodiments, all signal values are assigned a sign. Only signed signal values in the support of a respective function are summed. Therein, filtering or discarding of some signal values may take place. The sum may be normalized. From the sum, properties of the noise may be determined, e.g., the coefficient b₃ up to errors, which may be reduced as compared to the embodiments described with respect to FIG. 12A. Determining a signal property such as a noise property is still substantially multiplication-free.

According an embodiment, N equidistantly recorded, discretized values of a test signal are provided in a test signal table. The number N may be any integer larger than 0. The table values are indexed by the numbers 0 to N−1. Indexing information is provided including an incremental value k. For determining properties of the carrier signal with angular frequency ω, k is set equal to 1. For determining properties of higher harmonics, e.g., of noise, k is set larger than 1. Indexing information is provided. The N signal values are provided with indexing information according to the mapping in equation (18) (“path” to an analog of an I integral) and according to the mapping in equation (19) (“path” to an analog of a Q integral). Further, 2n sets of signs are assigned to the signal values or a part thereof based on the indexing information, where n≧1. Typically, each respective part of signal values to which signs are assigned depends on a parameter α, wherein, typically, the parameter α determines the support of a rectangular reference function. Values outside of a respective support are ignored or discarded. Each of the 2n sets of signed signal values is summed to 2n sums. The sums may be weighted or normalized. The n sums related to an I integral are summed to an analog of an I integral, the n sums related to a Q integral are summed to an analog of a Q integral. From the final two sums, a signal property may be determined. In one embodiment, a signal property of a frequency part or harmonic specified by the value k may be determined. Typically, amplitude, phase, and power of the analyzed frequency part may be determined.

According to embodiments described herein, a method of analyzing a periodic signal is provided, in one embodiment a method of analyzing noise in a test signal. Such a method is schematically illustrated in FIG. 4. The method includes providing signal values 410. The method may further include grouping of the signal values 460. Therein, grouping may include providing indexing information according to any of the embodiments described herein. Grouping may include assigning signs according to any of the embodiments described herein. The method may further include summing of signal values 440. Therein, summing may be a summing according to any of the embodiments described herein. A signal property, in one embodiment a noise property may be determined 450. Determining a noise property may be a determining according to any of the embodiments described herein.

Signal analysis, in one embodiment analysis of a periodic signal, according to any embodiment described herein, may be performed on a suitable piece of hardware, yielding further embodiments. In one or more embodiments, a suitable piece of hardware may be a dedicated piece of hardware, possibly a dedicated piece of hardware with limited resources. Such a piece of hardware may be from the group including Systems on Chip (SoCs) and Field Programmable Gate Arrays (FPGAs). Signal analysis may, e.g., be performed as part of a built-in self-test or for any other purpose. In other embodiments, the suitable piece of hardware may be a general-purpose piece of hardware such as a computer, possibly programmed by appropriate software.

According to embodiments described herein, an apparatus for the analysis of a signal is provided, in one embodiment an apparatus for the analysis of a periodic signal, e.g., a noise-affected carrier signal such as the signal of equation (5). In typical embodiments, the apparatus is included in a single semiconductor element such as a chip, computer chip, SoC, or FPGA. In other embodiments, the apparatus is included in a computer, e.g., a personal computer. The apparatus or any component thereof may be configured to provide, respectively process values such as signal values or indices either sequentially or in blocks of values.

According to embodiments, which may be combined with other embodiments described herein, the apparatus may include a signal value holding system. A signal value holding system may include one of the following: a space for holding at least one signal value, a space for storing at least one signal value, a space for holding a list or table of signal values, a space for storing a list or table of signal values. Typically such a space is a memory area, e.g., a memory area on a chip, computer chip, SoC, or FPGA. In one or more embodiments, the signal value holding system may hold at least one signal value during operation of the apparatus. In other embodiments, the signal value holding system may store at least one signal value during operation of the apparatus and also during non-operation.

According to embodiments, which may be combined with other embodiments described herein, the signal value holding system may include an input interface. The input interface may be configured to receive input from other components of the apparatus, e.g., input triggering the signal value holding system to output or send one or more signal values. The signal value holding system may include an output interface. The output interface may be configured to be connected to other components of the apparatus, e.g., to a signal value processing system or at least one signal processing unit. The output interface may be configured to output or send one or more signal values, possibly along with any number of copies of such a value or such values.

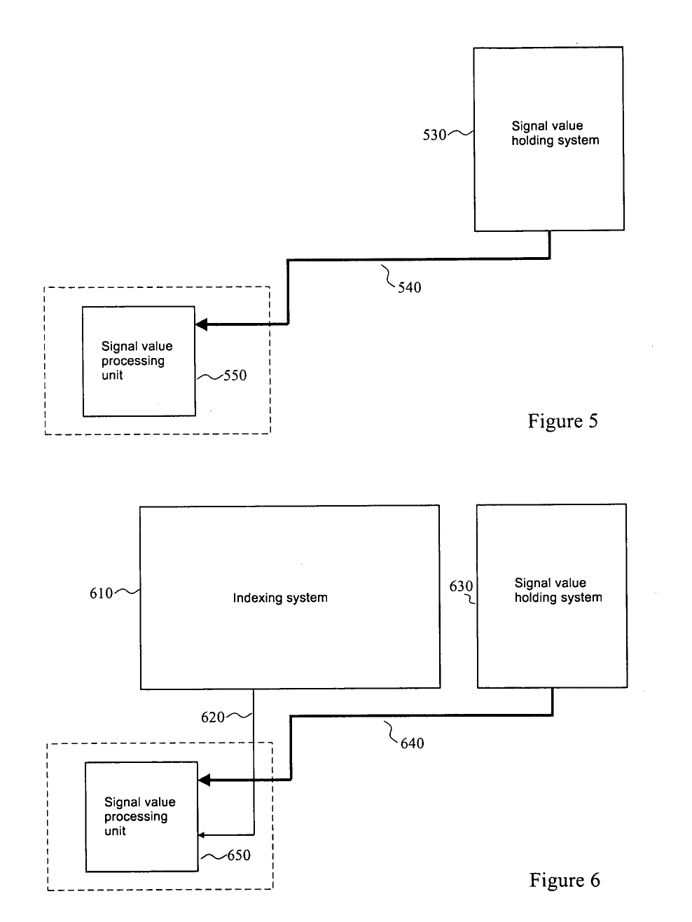

As illustrated in FIG. 5, the apparatus may include a signal value holding system 530 according to embodiments described herein.

According to embodiments, which may be combined with other embodiments described herein, the apparatus includes a signal value processing unit. A signal value processing unit may be part of a signal value processing system. A signal value processing unit may be included on a chip, computer chip, SoC, or FPGA. In typical embodiments, a signal value processing unit includes or consists of an accumulator. A signal value processing unit may be configured to assign signs to the signal values. A signal value processing unit may include a sign assigning unit configured to assign signs to the signal values. A signal value processing unit, e.g., an accumulator included in the signal value processing unit, may be configured to sum signal values. In typical embodiments, a signal value processing system is configured to sum signed signal values, e.g., signed signal values provided with signs by the signal processing unit or a sign assigning unit included in the signal processing unit. A signal processing unit may be configured to filter or discard signal values. According to one or more embodiments, a signal processing unit may include a filter unit configured to filter or discard signal values, e.g., signed signal values, e.g., signed signal values provided with signs by the signal value processing unit. According to other embodiments, a signal processing unit may include a filter unit configured to filter or discard signal values, and the signal processing unit may be configured to assign signs to the filtered signal values, or may include a sign assigning unit configured to assign signs to the filtered signal values. A signal value processing unit, e.g., an accumulator included therein, may be configured to sum filtered signal values, e.g., signed signal values filtered by the signal value processing unit or filtered signal values provided with signs by the signal value processing unit. A signal value processing unit may be configured to perform multiplication operations, e.g., a limited number of multiplication operations such as 1 or 2 or less than 10 multiplication operations.

According to embodiments, which may be combined with other embodiments described herein, a signal value processing unit may include an input interface. The input interface may be configured to receive input from other components of the apparatus, e.g., input in form of at least one signal value or indexing information or a combination thereof. The input interface may include input channels to the signal processing unit, to a filter unit, to a sign assigning unit or to any combination thereof. A signal value processing unit may include an output interface. The output interface may be configured to be connected to other components of the apparatus, e.g., to another signal value processing unit. The output interface may be configured to output or send one or more signals, e.g., a signal representing a value obtained by processing at least one signal value, e.g., a sum of signal values.

As illustrated in FIG. 5, an apparatus for the analysis of a signal may include a signal value processing unit 550 according to embodiments described herein. Further, according to one or more embodiments, FIG. 5 illustrates a communication connection 540 between the signal value holding system 530 and the signal value processing unit 550. According to embodiments, which can be combined with other embodiments described herein, a connection may be any sort of wire or lead or any other device configured for signal transmission. Any connection may connect corresponding input und output interfaces of components of the apparatus. According to one or more embodiments illustrated in FIG. 5, the signal processing unit 550 may be part of a signal value processing system as indicated by the dashed line around the signal value processing unit 550.

According to embodiments, which may be combined with other embodiments described herein, the apparatus for the analysis of a signal may include more than one signal value processing unit, e.g., 2, 3, 4, 6, 8, 10, 12 signal value processing units. In typical embodiments, these signal value processing units may be identical or similar to the signal value processing unit according to embodiments described in the foregoing. In other embodiments, at least one of these additional signal value processing units is different. For example, the at least one different signal value processing unit may be configured to process the output of at least one other signal processing unit. The at least one different signal value processing unit may, e.g., be configured to sum the output of other signal processing units. The at least one different signal processing unit may be configured to perform multiplication operations or other arithmetic operations such as taking the square root of a value or applying a trigonometric function to a value. The additional signal value processing unit or units may be included on a chip, computer chip, SoC, or FPGA, typically on the same chip, computer chip, SoC, or FPGA if the first signal processing unit is included in one of such devices.

The apparatus for the analysis of a signal, e.g., a periodic signal, may, according to embodiments, which may be combined with other documents described herein, be configured to provide information about at least one property of the signal, e.g., the periodic signal. Typically, the provided information is at least one value characterizing the at least one property of the signal. The at least one signal property may be at least one property of a carrier signal, e.g., the amplitude, phase, power or any combination thereof, or at least one property of noise, e.g., an amplitude, phase, power or any combination thereof. The provided information may include amplitude, phase, or power of a frequency part of the signal, e.g., of the carrier signal, or total harmonic distortion or spurious-free dynamic range, or any combination thereof. In typical embodiments, the apparatus is configured to provide information about at least one property of the signal on the basis of processed signal values. Processed signal values may represented by one of the following, any number of the following or any combination of one or any number of the following: a sum, a sum of signal values, a sum of signed signal values, a sum of filtered signal values, a sum of filtered signed signal values, a weighted or normalized sum of any of the foregoing. Alternatively, processed signal values may be represented by other quantities.

FIG. 5 illustrates an apparatus for the analysis of a signal according to embodiments described herein. According to one or more embodiments, the apparatus includes a signal value holding system 530 connected via connection 540 with a signal value processing unit 550. The signal value holding system 530 may be configured to provide N signal values to the signal value processing unit 550 via connection 540. The signal value processing unit may be configured to assign signs to the N signal values, e.g., a positive sign to the first half of the N signal values received by the signal value processing unit 530, and a negative sign to the second half of the N signal values as explained in the text passages relating to the top graph in FIG. 11. The signal value processing unit 530 may be configured to sum the signed signal values to a sum. The signal value processing unit 530 may be configured to provide information about a signal property, e.g., about the amplitude of a carrier signal given that the phase of the carrier signal is known to have a fixed value such as zero. Providing information about a signal property may be based on the sum. For example, the sum may be taken to approximate an I integral according to equation (12) with α=0, and the amplitude may be derived from equation (14) with Q=0 in case the phase φ is zero. According to embodiments, the apparatus illustrated by FIG. 5 may configured to perform any method for the analysis of a signal according to embodiments described herein. According to other embodiments, the apparatus illustrated by FIG. 5 is used to perform any method for the analysis of a signal according to embodiments described herein.

According to embodiments, which may be combined with other embodiments described herein, the apparatus for signal analysis includes an indexing system. The indexing system may be included on a chip, computer chip, SoC, or FPGA. The indexing system may be configured to provide indexing information. Indexing information may include first indexing information. Indexing information may include first and second indexing information. The indexing system may include an input interface. The input interface may be configured to receive input, e.g., input in form of a start signal for starting operation of the apparatus. The indexing system may include an output interface. The output interface may be configured to be connected to other components of the apparatus, e.g., to at least one signal value processing unit, a signal value holding system or any combination thereof. The output interface may include one, two, three or more output channels configured to output first, second, third indexing information or other information such as process control signals. Process control signals may, e.g., include signals synchronizing processes in different components such as signal value holding system and signal value processing units.

FIG. 6 illustrates an apparatus for the analysis of a signal such as a periodic signal. According to embodiments illustrated in FIG. 6, the apparatus includes a signal value holding system 630, a signal value processing unit 650 connected to the signal value holding system 630 via a connection 640, and an indexing system 610. As illustrated in FIG. 6, the indexing system is connected to the signal processing unit 650 via connection 620. According to one or more embodiments, the indexing system may be connected to the signal value holding system, e.g., to synchronize output of signal values from the signal value holding system with indexing information, which is output by the indexing system. According to one or more embodiments illustrated in FIG. 6, the signal processing unit 650 may be part of a signal value processing system as indicated by the dashed line around the signal value processing unit 650.

According to embodiments, the apparatus illustrated by FIG. 6 is configured to carry out the method described above with respect to FIG. 5 or any method for the analysis of a signal according to embodiments described herein. According to other embodiments, the apparatus illustrated by FIG. 6 is used to carry out the method described above with respect to FIG. 5 or any method for the analysis of a signal according to embodiments described herein.

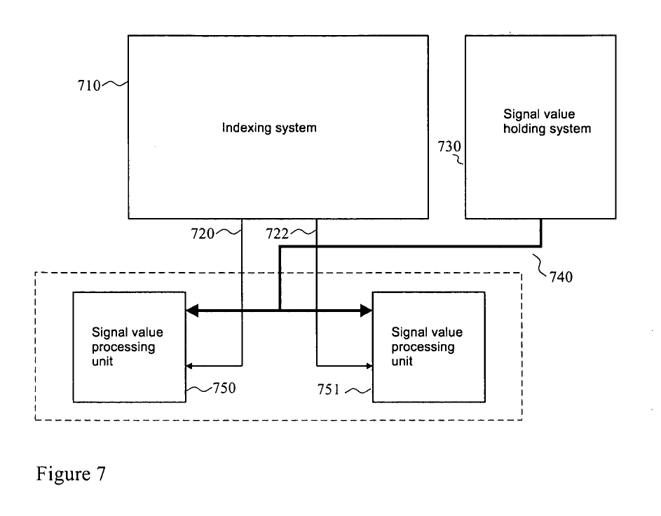

FIG. 7 illustrates an apparatus for the analysis of a signal such as a periodic signal. According to embodiments illustrated in FIG. 7, the apparatus includes a signal value holding system 730, a signal value processing unit 750 connected to the signal value holding system 730 via a connection 740, a signal value processing unit 751 connected to the signal value holding system 730 via a connection 740, and an indexing system 710. As illustrated in FIG. 7, the indexing system is connected to the signal processing unit 750 via connection 720 and to the signal processing unit 751 via connection 722. According to one or more embodiments, the indexing system may be connected to the signal value holding system, e.g., to synchronize output of signal values from the signal value holding system with indexing information, which is output by the indexing system. Components of the apparatus may include corresponding input or output channels or a combination thereof. According to one or more embodiments illustrated in FIG. 7, the signal processing units 750 and 751 may be part of a signal value processing system as indicated by the dashed line around the signal value processing units 750 and 751.

According to embodiments, the apparatus illustrated in FIG. 7 is configured to carry out the method described with respect to FIG. 2. In one or more embodiments, the apparatus is configured to carry out the method according to one embodiment schematically illustrated in FIG. 2, namely an embodiment related to forming an I integral and a Q integral. In other embodiments, the apparatus is configured to carry out the method according to a further embodiment schematically illustrated in FIG. 2, namely an embodiment related to forming an I integral for a reference function which is a superposition of rectangular functions. According to embodiments, the apparatus illustrated in FIG. 7 is configured to carry out any method for the analysis of a signal according to embodiments described herein. According to embodiments, the apparatus illustrated in FIG. 7 is used to carry out the above methods any method for the analysis of a signal according to embodiments described herein.

According to embodiments, which may be combined with other embodiments described herein, the indexing system includes or consists of a counting unit. A counting unit may be configured to provide indexing information in the form of consecutive integers, e.g., the integers 0 to N−1 if N signal values are provided by a signal value holding system. Alternatively, a counting unit may be configured to provide indexing information in any other form.

In one or more embodiments, which may be combined with other embodiments described herein, the indexing system includes a shifting unit configured to provide indexing information by a shifting operation, e.g., on other indexing information. For example, the shifting unit may shift the indexing information provided by the counting unit in form of integers 0 to N−1, e.g., by adding N/4 or the integer closest to N/4. The shifting unit may shift indexing information in any other way. A shifting unit may, e.g., be included or used in embodiments related to Q integrals. In one or more embodiments, which may be combined with other embodiments described herein, the indexing system includes a modulo operation unit configured to provide indexing information by a modulo operation, e.g., on other indexing information. For example, a modulo operation unit may execute a mod N operation on indices 0 to N−1, which are shifted by N/4. An indexing system may include two or more modulo operation units.

In one or more embodiments, which may be combined with other embodiments described herein, the indexing system includes an incrementing unit configured to provide indexing information by an incrementing operation, e.g., on other indexing information. For example, an incrementing unit may be associated with an increment k, which is an integer. The incrementing unit may increment indices 0 to N−1 respectively by multiplication with k, thereby generating indices 0, k, 2k, . . . , (N−1)k. Alternatively, an incrementing unit may, e.g., provide indices 0, k, 2k, . . . , (N−1)k irrespective of other indexing information. An incrementing unit may, e.g., replace a counting unit, or may be present along with a counting unit. An incrementing unit may, e.g., be included or used in embodiments related to the determination of at least one property of frequency parts of a test signal with angular frequency kω, e.g., at least one noise property.

In an embodiment, the indexing system includes a counting unit, a shifting unit and at least one modulo unit, and the indexing system is configured to provide indexing information according to equation (18) or equation (19) or a combination thereof, wherein k≠1. In another embodiment, the indexing system includes a counting unit, an incrementing unit, a shifting unit and at least one modulo unit, and the indexing system is configured to provide indexing information according to equation (18) or equation (19) or a combination thereof.

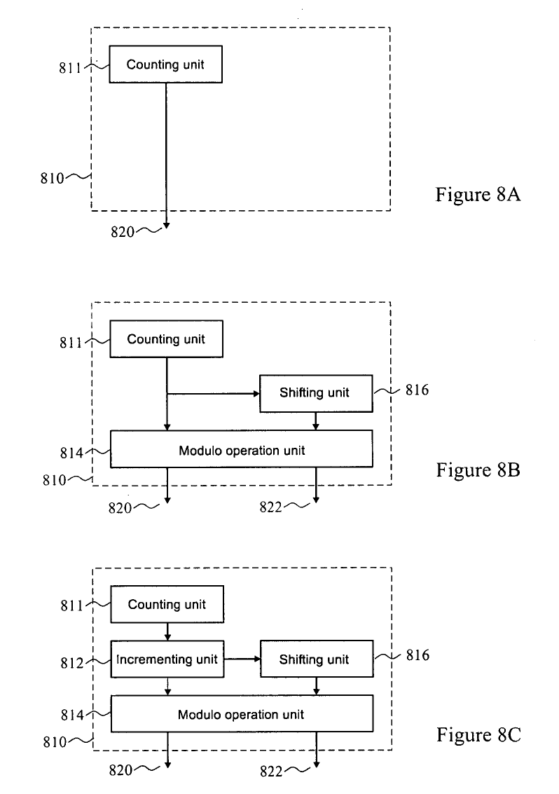

FIGS. 8A, 8B, 8C illustrate variants of an indexing system, represented by the respective dashed line, according to embodiments, which may be combined with other embodiments described herein. FIG. 8A illustrates an indexing system 810 including a counting unit 811 configured to provide or output indexing information. FIG. 8A further illustrates a connection 820 connecting to other components of an apparatus for the analysis of a signal, e.g., a signal processing unit. Connection 820 may serve to send or provide indexing information to other apparatus components.

FIG. 8B illustrates an indexing system further including a shifting unit 816 and modulo operation unit 814. The shifting unit is configured to shift indexing information provided by the counting unit 811, respectively a copy thereof. The modulo operation unit is configured to apply a modulo operation to indexing information provided by the counting unit 811 and to indexing information provided by the shifting unit. The modulo operation unit 814 is configured to provide or output first indexing information via connection 820 and second indexing information via connection 822. Instead of one modulo operation unit, there may be two modulo operation units, one receiving indexing information from the counting unit and providing or outputting indexing information via connection 820, and the other receiving indexing information from the shifting unit and providing or outputting indexing information via connection 822.

FIG. 8C illustrates an indexing system 810 further including an incrementing unit 812 configured to increment indexing information provided by the counting unit 811. The shifting unit 816 is configured to shift indexing information provided by the incrementing unit 812, respectively a copy thereof. The modulo operation unit 814 is configured to apply a modulo operation to indexing information provided by the incrementing unit 812 and to indexing information provided by the shifting unit. The modulo operation unit is configured to provide or output first indexing information via connection 820 and second indexing information via connection 822. Instead of one modulo operation unit, there may be two modulo operation units, one receiving indexing information from the counting unit and providing or outputting indexing information via connection 820, and the other receiving indexing information from the shifting unit and providing or outputting indexing information via connection 822. Connections 820 or 821 or both may be connected to an output interface of the indexing system, e.g., output channels included in the output interface of the indexing system.

Embodiments of the indexing system illustrated in FIG. 8A may, e.g., be included in the apparatus illustrated in FIG. 5 or FIG. 6. Such an indexing system, respectively the apparatus, may, e.g., be used to perform a method described with respect to FIG. 1 or FIG. 5. Embodiments of the indexing system illustrated in FIG. 8B may, e.g., be included in the apparatus illustrated in FIG. 7. Such an indexing system, respectively the apparatus, may, e.g., be used to perform a method described with respect to FIG. 2, respectively FIG. 7. Embodiments of the indexing system illustrated in FIG. 8C may, e.g., be included in the apparatus illustrated in FIG. 7. Such an indexing system, respectively the apparatus, may, e.g., be used to perform a method described with respect to FIGS. 2, 12A, 12B, respectively FIG. 7.

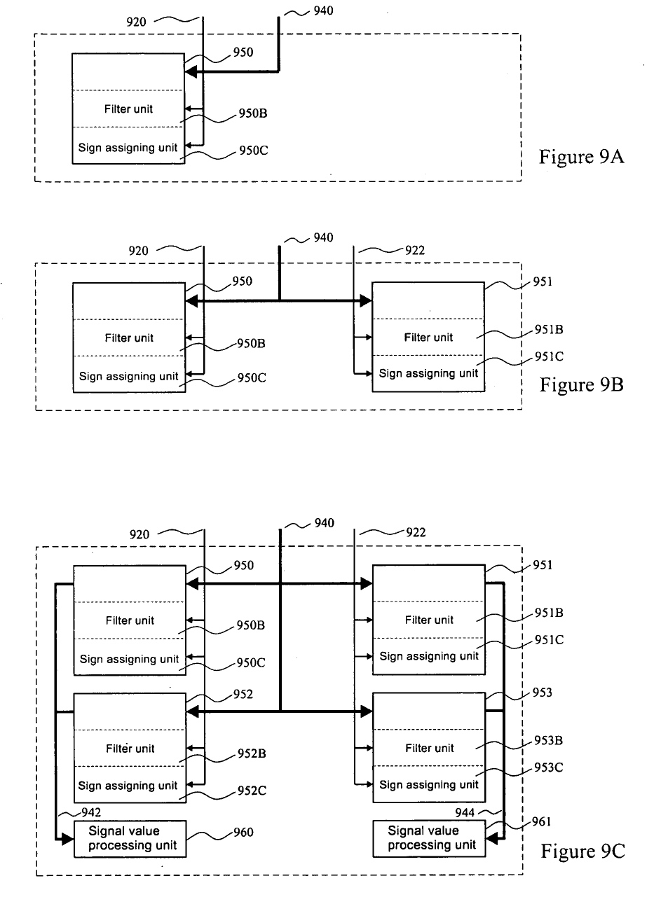

FIGS. 9A, 9B, 9C illustrate variants of a signal processing system, represented by the respective dashed line, according to embodiments, which may be combined with other embodiments described herein. As illustrated in FIG. 9A, according to embodiments, a signal processing unit 950 including a filter unit 950B and a sign assigning unit 950C is provided. The sign assigning unit 950C may be configured to assign signs to signal values provided to the signal processing unit via connection 940. Connection 940 may be configured connect to a signal value holding system, e.g., via respective input or output interfaces. The sign assigning unit may be configured to assign signs to signal values based on indexing information provided via connection 920. Connection 920 may be configured to connect to an indexing system, e.g., via respective input or output interfaces. The filter unit 950C may be configured to filter or discard signal values provided to the signal processing unit via connection 940. The sign assigning unit may be configured to filter or discard signal values based on indexing information provided via connection 920. According to one or more embodiments, a filter unit may be absent, e.g., in applications, where no filtering is needed, i.e., the filter criterion or filter condition may be absent, e.g., in application relating to reference signals according to equations (10) or (11) with α=0. The signal processing unit 950 may be configured to sum signal values to a sum, typically signed signal values or filtered signed signal values. The signal value processing unit 950 may include an accumulator configured to sum signal values, typically signed signal values. The signs may be assigned by the sign assigning unit 950C, and the filter unit 950B may filter the signed values. In another example, the filter unit 950B may filter the signal values and the sign assigning unit 950C may assign signs to the filtered signal values. The signal processing unit 950 may be configured to perform further arithmetic operations, e.g., weighting or normalizing the sum using multiplication. The signal value processing unit 950 may be configured to determine at least one property of a signal.

As illustrated in FIG. 9B, according to embodiments, a further signal processing unit 951 including a filter unit 951B and sign assigning unit 951C is provided. In FIG. 9B, the signal processing unit 951 is connected to connection 940, which may be configured to provide signal values or copies thereof to the signal processing unit 951. Further, the signal processing unit 951 is connected to connection 922, which may be configured to provide indexing information to the signal processing unit 951. The indexing information may be different from the indexing information provided via connection 920, e.g., in embodiments related to an I integral and a Q integral as in embodiments described with respect to an embodiment of FIG. 2. In other embodiments, the indexing information provided via connections 920 and 922 may be the same, e.g., in embodiments related to superpositions of rectangular reference signals as in another embodiment of FIG. 2. The signal processing unit 951 may be analog or similar to the signal processing unit 950. In other embodiments, the signal processing unit 951 may be different from the signal processing unit 950, e.g., differing in the presence or absence of a filter unit. An output of the signal processing units may be processed by at least one further component, which is not illustrated, e.g., by another signal processing unit configured to sum the output of the signal processing units 950 and 951. The signal value processing units 950, 951 may be configured to determine, individually or together, at least one property of a signal.

As illustrated in FIG. 9C, according to embodiments, four further signal processing units 952, 953, 960, and 961 are provided. Signal processing units 952 and 953 include respective filter units 952B, 953B and respective sign assigning units 952C, 953C. The signal processing units 952 and 953 are connected to connection 940, e.g., by corresponding interfaces, and are configured to receive signal values or copies thereof via connection 940. The signal processing unit 952 is connected to connection 920 and is configured to receive indexing information via connection 920. The signal processing unit 953 is connected to connection 922 and is configured to receive indexing information via connection 922. The signal processing units 952, 953 may be analog or similar to the signal processing unit 950. In other embodiments, the signal processing units 952, 953 may be different from the signal processing unit 950, e.g., differing in the presence or absence of a filter unit. The signal processing unit 960 is connected to signal processing units 950, 952 via connection 942, e.g., by corresponding input or output interfaces. The signal processing unit 961 is connected to signal processing units 951, 953 via connection 944, e.g., by corresponding input or output interfaces. According to one or more embodiments, signal processing units 960, 961 may be analog or similar to processing unit 950. In other embodiments, signal processing units 960, 961 may be different from signal processing unit 950, e.g., differing in aptitude to perform further, possibly more complex arithmetic operations. The signal value processing units 960, 961 may be configured to determine, individually or together, at least one property of a signal.

Embodiments of a signal processing system illustrated in FIG. 9A may, e.g., be included in embodiments of the apparatus illustrated in FIG. 5 or FIG. 6. Such a signal processing system, respectively the apparatus, may, e.g., be used to perform a method described with respect to FIG. 1 or FIG. 5. Embodiments of the signal value processing system illustrated in FIG. 9B may, e.g., be included in the apparatus illustrated in FIG. 7. Such a signal value processing system, respectively the apparatus, may, e.g., be used to perform a method described with respect to FIG. 2, respectively FIG. 7. Embodiments of the signal value processing system illustrated in FIG. 9C may, e.g., be included in the apparatus illustrated in FIG. 7. Such a signal value processing system, respectively the apparatus, may, e.g., be used to perform a method described with respect to FIGS. 2, 3, 12A, 12B, respectively FIG. 7.

According to embodiments described herein, an apparatus for the analysis of a signal may include any number of signal value processing units. For example, such an apparatus may include 1, 2, 3, 4, 6, 8, 10, 2n+2 signal processing units, which may be analog to or similar to the signal processing unit 950 or the signal processing unit 960, where n is an integer. The integer n may be related to a number of rectangular reference functions superposed to form a reference function.

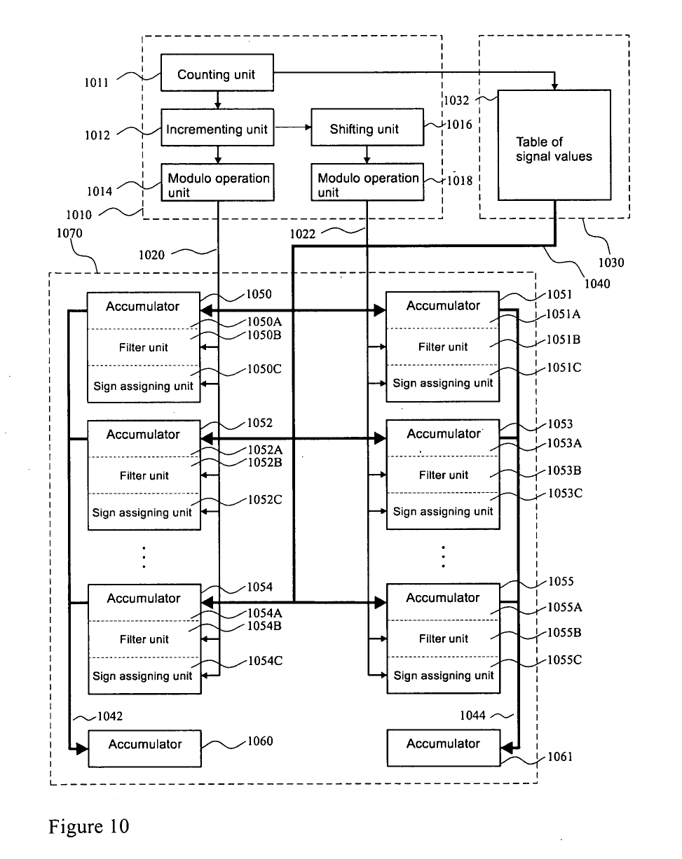

FIG. 10 illustrates embodiments of an apparatus for the analysis of a signal according to embodiments. The apparatus includes a signal value holding system 1030, an indexing system 1010 and a signal processing system 1070. The indexing system 1010 includes a counting unit 1011, an incrementing unit 1012, a shifting unit 1016, and two modulo operation units 1014, 1018. The indexing system and its components may, e.g., have properties as discussed with respect to FIG. 9, or may have properties as in other embodiments described herein.

The signal value holding system 1030 includes a table of signal values 1032. Alternatively, the signal value holding system may hold only one signal value or may hold several signal values, e.g., in applications where signal values are provided on-the-fly. The signal value holding system may have any property as described herein with respect to embodiments.

The signal processing system 1070 includes 2n+2 signal processing units, of which 8 are illustrated exemplarily, namely signal processing units 1050, 1051, 1052, 1053, 1054, 1055, 1060, 1061. However, n may be any integer larger than or equal to 1. Signal processing units 1050, 1051, 1052, 1053, 1054, 1055 include an accumulator, a filter unit and a sign assigning unit each, namely accumulators 1050A, 1051A, 1052A, 1053A, 1054A, 1055A, filter units 1050B, 1051B, 1052B, 1053B, 1054B, 1055B, and sign assigning units 1050C, 1051C, 1052C, 1053C, 1054C, 1055C. The signal processing units may have any property described herein with respect to embodiments, e.g., properties described with respect to FIG. 9.

The indexing system 1010 is connected to the signal processing system 1070 via connections 1022. In one embodiment modulo operation unit 1014 is connected to signal processing units 1050, 1052, 1054 via connection 1020, and modulo operation unit 1018 is connected to signal processing units 1051, 1053, 1055 via connection 1022. The signal value holding system 1030 is connected to the signal processing system 1070 via connection 1040. In one embodiment, the table of signal values 1032 is connected to signal processing units 1050, 1051, 1052, 1053, 1054, 1055 via connection 1040. Signal processing units 1050, 1052, 1054 are connected to signal processing unit 1060 via connection 1042, and signal processing units 1051, 1053, 1055 are connected to signal processing unit 1061 via connection 1044. The indexing system 1010 may be connected to the signal value holding system 1030, e.g., for synchronization or triggering of output, in one embodiment the counting unit 1011 may be connected to the table of signal values 1032. All connected systems or system components may include corresponding input or output interfaces, e.g., input or output channels.

Embodiments of an apparatus for the analysis of a signal, e.g., embodiments illustrated in FIG. 10, may be configured to perform or may be used to perform any embodiment of a method for the analysis of a signal described herein. In any embodiment of a method for the analysis of a signal or in any embodiment of the use of an apparatus for the analysis of a signal, values such as signal values or indices may be provided or processes either sequentially or in blocks of values. In one or more embodiments, embodiments of an apparatus as described herein, e.g., embodiments illustrated in FIG. 10, may be configured to perform or be used to perform a method according to embodiments that follow.

According to embodiments, a method for the analysis of a signal, e.g., a periodic signal, is provided. The method includes providing N signal values, e.g., N discretized signal values recorded in equidistant time intervals. The N signal values may be provided by a table of signal values. A linear counting unit serves to address signal values, e.g., in a table of signal values. An increment unit is also addressed by the linear counting unit. The increment unit increments a current value by an integer k when addressed by the linear counting unit. The increment unit provides base indexing information. A first modulo operation unit processes the base indexing information by performing a mod N operation. The first modulo operation unit provides first indexing information. A shifting unit processes the base indexing information by adding N/4k or an integer value closest to N/4k, and a second modulo operation unit performs a mod N operation thereon. The second modulo operation unit provides second indexing information.

The first indexing information is provided to n signal processing units including a filter unit and a sign assigning unit, where n is larger than or equal to one. Typically, the indexing information is passed sequentially and synchronous with a signal value provided by the table of signal values. In each of the n signal processing units the filter unit checks, whether the provided signal value complies with a filter criterion based on the first indexing information. A signal value not complying with a filter criterion is filtered out. In each of the n signal processing units a positive or negative sign is assigned to a signal value based on the first indexing information. Signed signal values not filtered out are summed to n sums in each of the n signal processing units. Each of the n sums may be further processed by the corresponding signal processing unit, e.g., be weighted or normalized. The n signal processing units pass the result of the processing, i.e., e.g., the n sums or weighted sums, to another signal processing unit, which sums the n sums to a sum related to an I integral and, possibly, performs further operations.

The second indexing information is provided to n signal processing units including a filter unit and a sign assigning unit, where n is larger than or equal to one. These n signal processing units may be different from the n signal processing units to which first indexing information is provided, or they may be the same. Typically, the indexing information is passed sequentially and synchronous with a signal value or copy of a signal value provided by the table of signal values. In each of the n signal processing units the filter unit checks, whether the provided signal value complies with a filter criterion based on the second indexing information. A signal value not complying with a filter criterion is filtered out. In each of the n signal processing units a positive or negative sign is assigned to a signal value based on the second indexing information. Signed signal values not filtered out are summed to n sums in each of the n signal processing units. Each of the n sums may be further processed by the corresponding signal processing unit, e.g., be weighted or normalized. The n signal processing units provide the result of the processing, i.e., e.g., the n sums or weighted sums, to another signal processing unit, which sums the n sums to a sum related to a Q integral and, possibly, performs further operations.

Based on the sum related to an I integral and based on the sum related to a Q integral, at least one signal property is determined, e.g., amplitude, phase, or power of a frequency part with angular frequency kω, or a combination thereof.

According to embodiments, which may be combined with any other embodiments, a signal processing unit may include more than one filter unit or more than one sign assigning unit or both. Such a signal processing unit may, e.g., replace n signal processing units, e.g., in a process branch computing a sum related to an I integral or a Q integral. Such a signal processing unit may include one accumulator, which is shared by the other components. Alternatively, such a signal processing unit may include more than one accumulator.

Further embodiments relate to an apparatus for analysis of a periodic signal including a data memory area configured to hold at least one signal value and to provide at least one signal value, and a program memory area with a program. In one or more embodiments, the program includes an indexing information program part configured to provide indexing information. The program may include a signal value processing program part including a signal value processing program portion. In one or more embodiments, the signal value processing program portion is configured to receive signal values from the data memory as input. In one or more embodiments, the signal value processing program portion is configured to receive indexing information from the indexing information program part as input. The signal processing program portion may be configured to assign signs to the signal values. In one or more embodiments, the signal value processing program portion is configured to assign signs to the received signal values. According to one or more embodiments, the signal value processing program portion is configured to assign signs based on indexing information. The signal processing program portion may be configured to sum the signed signal values to a first sum. The program may include an evaluation program part configured to determine at least one signal property based the first sum.

In further embodiments, a computer program product for the analysis of a signal is provided. The computer program product includes program code, which, when loaded into a computer, is configured to carry out a method for the analysis of a signal according to any of the embodiments described herein. The computer program product may be data carrier, e.g., a CD ROM or DVD, or may be a data stream including the computer program, e.g., a data stream which may be downloaded from the internet.

In further embodiments, a computer program for the analysis of a signal is provided. The computer program includes program code, which, when loaded into a computer, is configured to carry out a method for the analysis of a signal according to any of the embodiments described herein.

In further embodiments, a computer for the analysis of a signal is provided. The computer includes program code, which, when run on the computer, is configured to carry out a method for the analysis of a signal according to any of the embodiments described herein.

While the foregoing is directed to embodiments, other and further embodiments may be devised by a combination of embodiments or in any other way without departing from the scope, and the scope is determined by the claims that follow.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for the analysis of a periodic signal comprising:
providing signal values;
assigning signs to the signal values;
summing the signed signal values to a first sum; and
determining at least one signal property on the basis of the first sum.

2. The method of claim 1, further comprising:
assigning first indexing information to the signal values.

3. The method of claim 2, comprising basing the assigning of signs to the signal values on the first indexing information.

4. The method of claim 2, comprising obtaining the first indexing information from indexing by consecutive integers, an incrementing operation and a modulo operation.

5. The method of claim 2 further comprising:
assigning second signs to the signal values;
summing the signal values, signed with the second signs, to a second sum; and
also basing the determining of at least one signal property on the second sum.

6. The method of claim 5, further comprising:
assigning second indexing information to the signal values; and
basing the assigning of second signs on the second indexing information.

7. The method of claim 6, comprising deriving the second indexing information from the first indexing information by a shifting operation and a modulo operation.

8. The method of claim 1, further comprising:
filtering the signed signal values according to a filter criterion or filtering the signal values according to a filter criterion and assigning signs to the filtered signal values;
summing the filtered signed signal values to a filtered sum; and
also basing the determining of at least one signal property on the filtered sum.

9. The method of claim 8, comprising basing the determination of at least one signal property on the sum of the first sum and the filtered sum.

10. The method of claim 1, wherein the periodic signal comprises a signal part with a carrier angular frequency and a signal part with an angular frequency that is an integer multiple of the carrier angular frequency.

11. The method of claim 1, comprising executing the method by circuitry of a single chip or field programmable gate array.

12. An apparatus for the analysis of a periodic signal comprising
a signal value holding system configured to provide signal values;
a first signal value processing unit configured to assign signs to the signal values and configured to sum the signed signal values to a first sum; and
wherein the apparatus is configured to provide, on the basis of the first sum, information about at least one property of the periodic signal.

13. The apparatus of claim 12 further comprising:
an indexing system configured to provide first indexing information to the signal values.

14. The apparatus of claim 13, comprising wherein the first signal processing unit is configured to assign the signs on the basis of the first indexing information.

15. The apparatus of claim 13, wherein the indexing system comprises:
a counting unit configured to provide indexing information including consecutive integers;
an incrementing unit configured to provide indexing information including incremented integers obtained by an incrementing operation on the consecutive integers; and
a modulo operation unit configured to provide indexing information including integers obtained by a modulo operation on the incremented integers.

16. The apparatus of claim 13, further comprising
a second signal value processing unit configured to assign second signs to the signal values and configured to sum the signal values, signed with the second signs, to a second sum; and
wherein the apparatus is configured to provide information about at least one property of the periodic signal on the basis of the first and second sum.

17. The apparatus of claim 16, comprising wherein the indexing system is configured to provide second indexing information to the signal values, and
wherein the second signal processing unit is configured to assign the second signs on the basis of the second indexing information

18. The apparatus of claim 17, wherein the indexing system comprises:
a shifting unit configured to provide indexing information including integers obtained by a shifting operation; and
a modulo operation unit configured to provide indexing information including integers obtained by a modulo operation.

19. The apparatus of claim 12, wherein the first signal value processing unit comprises:
a filter unit configured to filter signed values according to a filter criterion;
wherein the first signal value processing unit is configured to sum filtered signal values to a filtered sum; and
wherein the apparatus is configured to provide information about at least one property of the periodic signal also on the basis of the filtered sum.

20. The apparatus of claim 12, wherein the periodic signal comprises a signal part with a carrier angular frequency and a signal part with an angular frequency that is an integer multiple of the carrier angular frequency.

21. The apparatus of claim 12, wherein the apparatus is comprised by a single chip or field programmable gate array.

22. An apparatus for analysis of a periodic signal comprising:
a data memory area configured to hold at least one signal value and to provide at least one signal value;
a program memory area with a program, the program comprising:
a signal value processing program part comprising:
a signal value processing program portion configured to assign signs to the signal values, and configured to sum the signed signal values to a first sum;
an evaluation program part configured to determine at least one signal property based on the first sum.

23. The apparatus of claim 22, wherein the program further comprises:
an indexing information program part configured to provide indexing information; and
wherein the signal value processing program portion is configured to assign signs based on the indexing information.

24. A computer program product for the analysis of a signal comprising:
a program code, which, when loaded into a computer, is configured to carry out a method for the analysis of a signal comprising:
providing signal values;
assigning signs to the signal values;
summing the signed signal values to a first sum; and
determining at least one signal property on the basis of the first sum.
